(19) United States
(12) Patent Application Publication
(10) Pub. No.: US 2008/0068781 A1
(43) Pub. Date: Mar. 20, 2008

(54) PORTABLE ELECTRONIC DEVICE

(75) Inventor: Young S. KIM, Los Altos, CA (US)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/857,165

(22) Filed: Sep. 18, 2007

Related U.S. Application Data
(60) Provisional application No. 60/845,659, filed on Sep. 18, 2006.

(30) Foreign Application Priority Data
Jul. 23, 2007 (KR) 73446/2007

(51) Int. Cl. H05K 7/16

(52) U.S. Cl. 361/600; 361/680; 361/682

(57) ABSTRACT

A portable electronic device includes a first main body extending in a longitudinal direction of the first main body; and a second main body connected to the first main body to be rotatable about a first hinge axis parallel to the longitudinal direction through use of a hinge part to be folded on or unfolded from the first main body, and to be rotatable about a second hinge axis parallel to the first hinge axis through use of a connection part formed on the hinge part to be turned over to switch an inner surface and an outer surface of the second main body above the first main body.

### PRIORITY

This application claims priority under 35 U.S.C. §119(a) to an application entitled “Portable Electronic Device” filed in the U.S. Patent and Trademark Office on Sep. 18, 2006 and assigned Provisional Patent Application No. 60/845,659 and to a Patent Application filed in the Korean Industrial Property Office on Jul. 23, 2007 and assigned Serial No. 2007-0073446, the contents of which are hereby incorporated by references.

### BACKGROUND OF THE INVENTION

1. Field of the Invention

The present invention relates generally to a portable electronic device, including a Digital Multimedia Broadcasting (DMB) phone, a game phone, a chatting phone, a camera phone, an MP3 phone, a cellular phone, a Personal Communication System (PCS), a Personal Digital Assistant (PDA), a Hand Held Phone (HHP), or the like, and more particularly to a portable electronic device having an improved User Interface (UI) environment not only in a phone mode, but also in a DMB mode or a game mode.

2. Description of the Related Art

In current mobile communication society, more people use portable electronic devices, such as a cellular phone, and the prevailing portable electronic devices are used not only for voice communications, but also for e-mail, Internet, photography, games, or the like. Considering the portability, designs of such portable electronic devices tend not only to be compact, slim, easy to grip, and light, but also are moving towards providing multimedia availability capable of seeking more service functions, such as providing entertainment contents, including games and amusements. Specifically, advent of the age that a user can access desired information by using the portable electronic device at anywhere and at any time has arrived.

Conventional portable electronic devices are classified into bar-type electronic devices or folder-type electronic devices according to their appearance, considering their portability, use convenience, or the like. An example of a folder-type portable electronic device is disclosed in U.S. Pat. No. 6,865,406, which is assigned to the assignee of the present application.

Further, portable electronic devices may also be classified into swing-type electronic devices and sliding-type electronic devices. Examples of sliding-type and swing-type portable electronic devices are disclosed in detail in U.S. Pat. No. 6,822,871 and U.S. Pat. No. 7,158,371, respectively, both of which are assigned to the assignee of the present application.

Although they are not seriously inconvenient to input data or check displayed data in a phone mode for voice communications or short text message transmission, conventional portable electronic devices have a problem in that the utility of the UI environment is decreased in the DMB mode or the game mode in multimedia-oriented environments.

For example, in the DMB mode, a user can conveniently use the terminals when a wider display unit is provided, key operation relating to the DMB mode is convenient, the wider display unit is mounted to be inclined for convenient watching, and stereo sound is implemented. However, the conventional portable electronic devices cannot provide such a convenient UI environment.

Furthermore, in the game mode, a wider display unit should be provided, and the operation for input data, i.e., the key press, should be speedy and accurate. However, the conventional portable electronic devices cannot provide such a convenient UI environment.

As a matter of course, the problem may be overcome by increasing the overall size of portable electronic devices to mount a wider display unit and arrange more keys. However, this is contrary to the current trend towards compactness and better portability.

### SUMMARY OF THE INVENTION

The present invention has been made to solve the above-mentioned problems occurring in the prior art, and the present invention provides a portable electronic device providing an improved User Interface (UI) environment which is convenient not only in a phone mode, but also in a DMB mode.

Also, the present invention provides a portable electronic device providing a wider display unit and convenient key operation in a DMB mode.

Further, the present invention provides a portable electronic device, which not only is convenient in a phone mode but also can provide a wider display unit and a convenient key operation environment in a game mode.

Furthermore, the present invention provides a portable electronic device which is slim and compact so that it is convenient for a user to carry the portable electronic device during a trip, and provides an improved UI environment.

In accordance with an aspect of the present invention, there is provided a portable electronic device including a first main body extending in a longitudinal direction of the first main body; and a second main body connected to the first main body to be rotatable about a first hinge axis parallel to the longitudinal direction through use of a hinge part to be Folded on or unfolded from the first main body, and rotatable about a second hinge axis parallel to the first hinge axis through use of a connection part formed on the hinge part to be turned over to switch an inner surface and an outer surface of the second main body above the first main body.

In accordance with another aspect of the present invention, there is provided a portable electronic device, wherein the connection part includes a pair of side hinge arms to provide the second hinge axis, and extending directions of the pair of the side hinge arms and the hinge part are perpendicular to each other.

In accordance with another aspect of the present invention, there is provided a portable electronic device, wherein the first main body includes a plurality of first keys arranged in a QWERTY key array or a 3×4 key array on an tipper surface of the first main body; a plurality of second keys positioned on a front surface of the first main body; and a battery apparatus positioned on a bottom surface and adjacent to the hinge part, and the second main body includes a plurality of third keys arranged in a number of keys array positioned on an inner surface of the second main body; and a display unit positioned on the inner surface of the second main body and adjacent to the plurality of the third keys.

In accordance with another aspect of the present invention, there is provided a portable electronic device, wherein the plurality of the third keys and the fourth keys include a number of keys used in a DMB mode.

In accordance with another aspect of the present invention, there is provided a portable electronic device, wherein the second main body and the connection part are shaped corresponding to a shape of the first main body.

In accordance with another aspect of the present invention, there is provided a portable electronic device including a QWERTY keypad extending in a longitudinal direction of the QWERTY keypad; and a display unit connected to the keypad to be rotatable about a first hinge axis parallel to the longitudinal direction through use of a hinge part to be folded on or unfolded from the keypad, or be inclined with respect to the keypad, and rotatable about a second hinge axis parallel to the first hinge axis through use of a connection part formed on the hinge part to be turned over to switch an inner surface and an outer surface of the display unit above the keypad.

In accordance with another aspect of the present invention, there is provided a portable electronic device, wherein the connection part surrounds at least one half of a side surface of the display unit.

### BRIEF DESCRIPTION OF THE DRAWINGS

The above and other aspects, features and advantages of the present invention will become more apparent from the following detailed description when taken in conjunction with the accompanying drawings, in which:

FIG. 1 is a top perspective view illustrating a portable electronic device in a closed state according to a first exemplary embodiment of the present invention;

FIG. 2 is a bottom perspective view illustrating a portable electronic device according to a first exemplary embodiment of the present invention;

FIGS. 3 and 4 are perspective views illustrating a state where a second main body of a portable electronic device is opened by rotating about a first hinge axis according to a first exemplary embodiment of the present invention;

FIG. 5 is a perspective view illustrating a state where a second main body of a portable electronic device rotates about a second hinge axis while the second main body maintains an opening state according to a first exemplary embodiment of the present invention;

FIG. 6 is a perspective view illustrating a state where a second main body of a portable electronic device rotates to reverse according to a first exemplary embodiment of the present invention;

FIG. 7 is a perspective view illustrating a portable electronic device, of which the reversed second main body is closed according to a first exemplary embodiment of the present invention; and

FIG. 8 is a perspective view illustrating a portable electronic device, of which a second main body is opened according to a second exemplary embodiment of the present invention.

### DETAILED DESCRIPTION OF THE EXEMPLARY EMBODIMENTS

Hereinafter, exemplary embodiments of the present invention will be described with reference to the accompanying drawings. In the following description of the present invention, a detailed description of known functions and configurations incorporated herein will be omitted when it may make the subject matter of the present invention rather unclear.

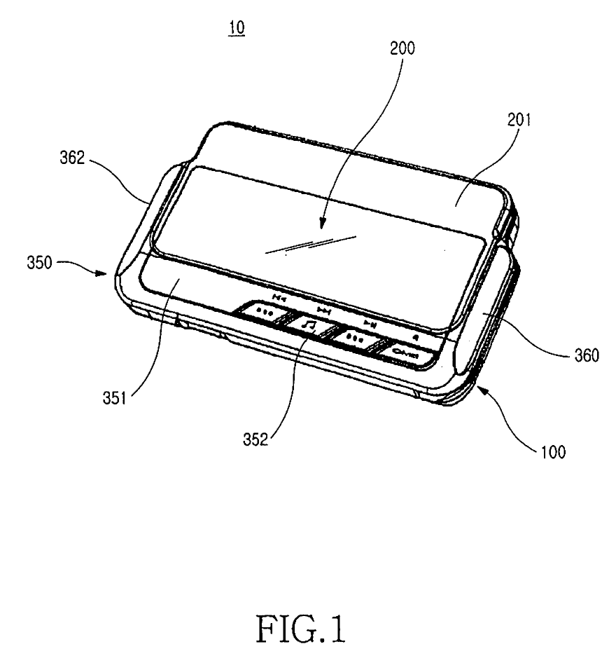

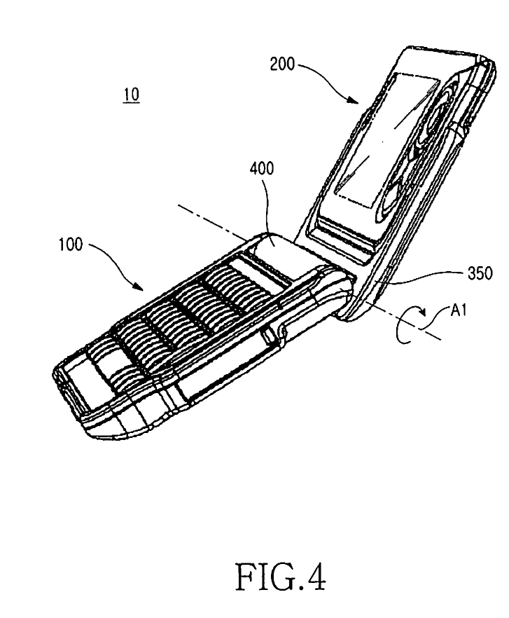

As shown in FIGS. 1, 2, 3, 4, and 5, a portable electronic device 10 according to the present invention refers to a portable electronic device having an improved User Interface (UI) environment which is convenient not only in a phone mode, but also in a DMB mode or a game mode. The portable electronic device 10 according to the first exemplary embodiment of the present invention includes a first main body 100 and a second main body 200 connected to each other. The second main body 200 is firstly rotatable through use of a hinge part 400 and is secondarily rotatable through use of a connection part 350. Specifically, the second main body 200 is rotatable about a first hinge axis A1 parallel to a longitudinal direction of the first main body 100, so that the second main body 200 can be folded on or unfolded from the first main body 100. Also, the second main body 200 is rotatable about a second hinge axis A2 parallel to the first hinge axis A1 so that the second main body 200 can be turned over to switch an inner surface 201 and an outer surface 202 thereof above the first main body 100.

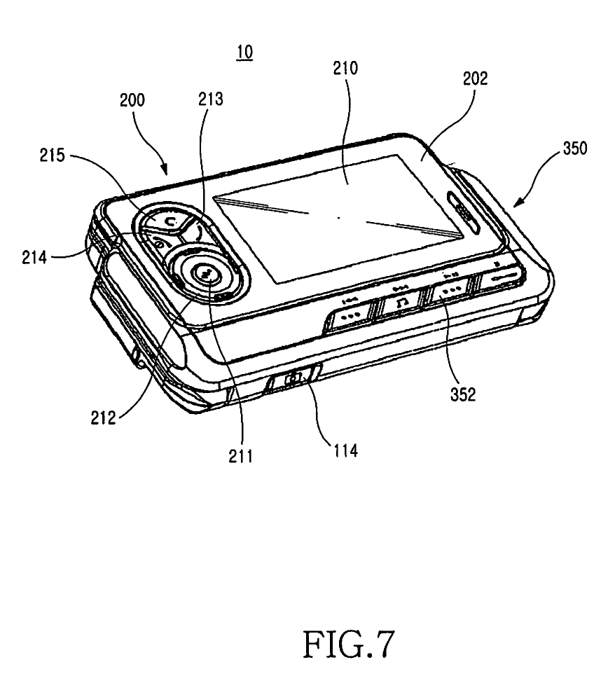

FIGS. 1 and 7 illustrate reversed states of the inner surface 201 and the outer surface 202 of the second main body 200, respectively. In addition, both the second main body 200 and the connection part 350 correspond to a shape of the first main body 100.

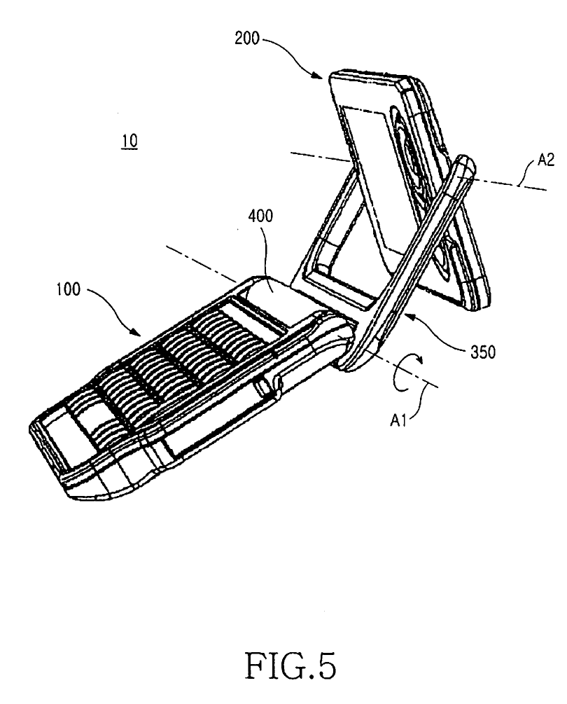

Further, the connection part 350 is integrally assembled with the hinge part 400, is connected to the second main body 200 and the hinge part 400, and surrounds a half or more of a side surface of the second main body 200. Furthermore, the connection part 350 includes a pair of side hinge arms 360 and 362 to provide the second hinge axis A2 as shown in FIG. 5. The extending direction of the pair of the side hinge arms 360 and 362 and the hinge part 400 are perpendicular to each other. The first main body 100 and the second main body 200 are connected by a flexible circuit (not shown) serving as an electric connectivity. The flexible circuit (not shown) passes through the hinge part 400 and the connection part 350 in the first main body 100 to connect to the second main body 200.

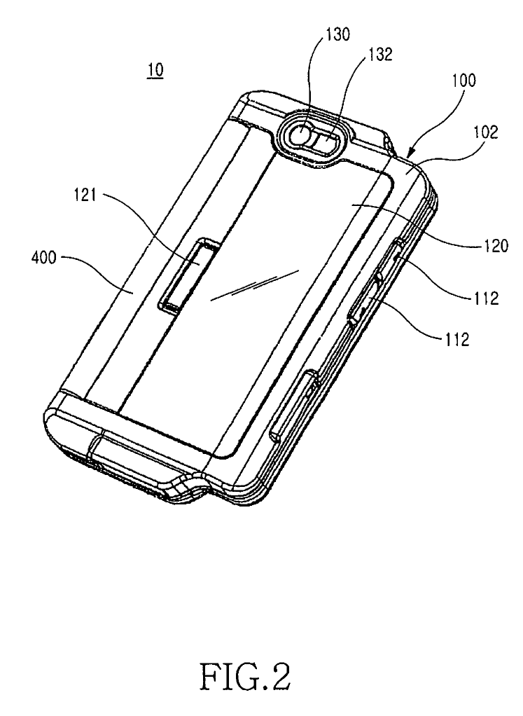

As shown in FIGS. 1, 2, and 3, the first main body 100 is shaped like a plate and extends in a longitudinal direction thereof. A plurality of first keys 110 forming a QWERTY keypad including a QWERTY key is positioned on an inner surface 101 of the first main body 100, and a plurality of second keys 112 is positioned on a front surface 103 of the first main body. As shown in FIG. 2, a battery apparatus 120, a camera lens 130, and a flash apparatus 132 are positioned on an outer surface 102 of the first main body 100. Reference number 121 denotes a knob for attaching and detaching the battery apparatus 120. The battery apparatus 120 (not shown) includes a plurality of battery cells, and is positioned adjacent to the hinge part 400.

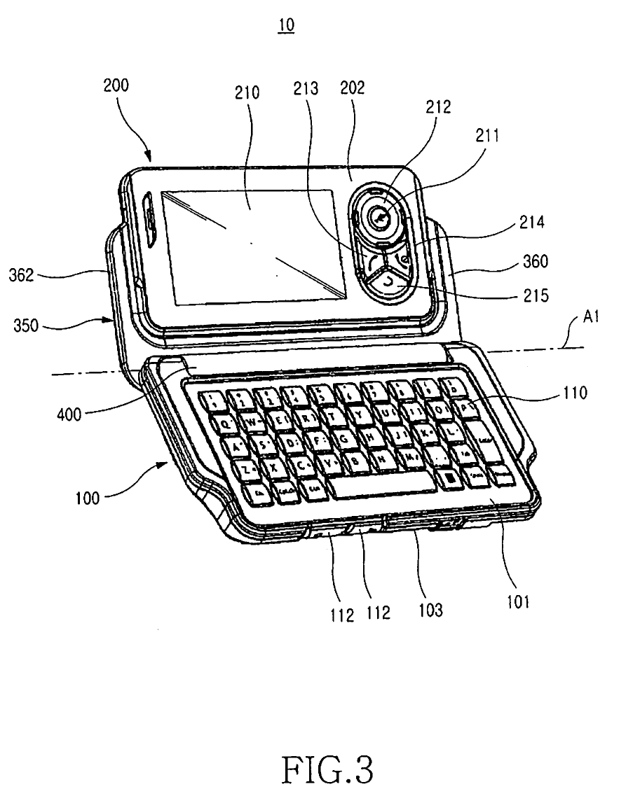

As shown in FIG. 3, the second main body 200 includes a plurality of third keys 211, 212, 213, 214, and 215 arranged in a number of keys array and positioned on the inner surface 202 thereof, and a display unit 210 positioned on the inner surface 202 thereof and adjacent to the plurality of the third keys 211, 212, 213, 214, and 215. The plurality of the third keys 211, 212, 213, 214, and 215 are used for DMB. Reference number 211 denotes a multi-directional center key, 212 denotes a navigation key, 213 denotes a send key, 214 denotes an end key, and 215 denotes a clear key. It is preferable that the display unit 210 includes a thin-type LCD. However, the display unit 210 may include a touch screen.

As shown in FIG. 1, the connection part 350 includes a plurality of fourth keys 352 arranged in a number of keys array on an outer surface 351 thereof, and the plurality of the fourth keys 352 are lineally arranged. The plurality of the fourth keys 352 are used for DMB. The plurality of the fourth keys 352 are used for playing music or a video clip, or used for fast-forwarding, rewinding, or pausing.

As shown in FIG. 3, if the second main body 200 is completely unfolded from the first main body 100, the plurality of the first keys 110 are exposed to be used by a user, and the display unit 210 is also held to be inclined, and thus it is convenient to use in the QWERTY mode.

As shown in FIG. 7, when the second main body 200 rotates by 180 degrees and is folded on the first main body 100 in a reversed state, the display unit 210, the plurality of the third keys 211, 212, 213, 214, and 215, and the plurality of the fourth keys 352 are exposed so that it is convenient to use in the DMB mode. The plurality of the third keys 211, 212, 213, 214, and 215 and the plurality of the fourth keys 352 are exclusive keys usable only in the DMB mode. Reference number 114 of FIG. 7 denotes a shutter key used in the camera mode.

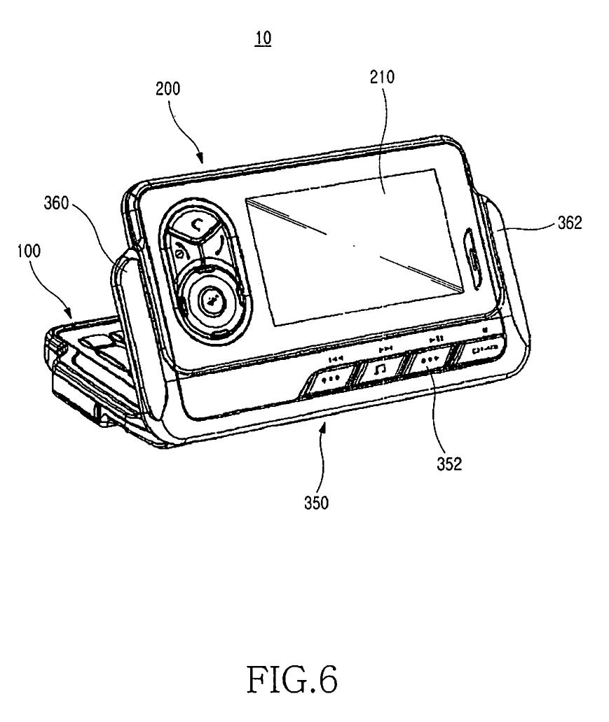

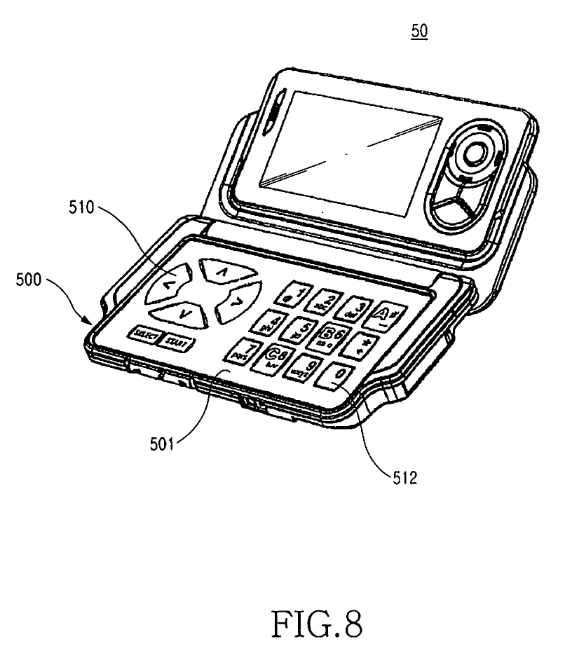

FIG. 8 is a perspective view illustrating a portable electronic device 50 according to a second exemplary embodiment of the present invention. As shown in FIG. 8, the portable electronic device 50 according to the second exemplary embodiment of the present invention includes a plurality of first keys which are positioned on an inner surface 501 of a first main body 500, and has an array of four-direction keys 510 and a 3×4 key 512, instead of the QWERTY key. The portable electronic device 50 according to the second exemplary embodiment of the present invention has been already described in detail with reference to the first exemplary embodiment (FIGS. 1, 2, 3, 4, 5, 6, and 7), except that the plurality of the first keys positioned on the inner surface of the first main body 50 includes the array of the four-direction key 510 and the 3×4 key 512, and thus the specific description will be omitted.

As described above, the portable electronic device according to the present invention achieves an advantage that it is convenient to use not only in the phone mode, but also in the QWERTY mode, the DMB mode, or the game mode while guaranteeing slimness and compactness. Therefore, the present invention can provide a convenient UI environment upon moving and traveling as well.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A portable electronic device comprising:
a first main body extending in a longitudinal direction of the first main body; and
a second main body connected to the first main body to be rotatable about a first hinge axis parallel to the longitudinal direction through use of a hinge part to be folded on or unfolded from the first main body, and rotatable about a second hinge axis parallel to the first hinge axis through use of a connection part formed on the hinge part to be turned over to switch an inner surface and an outer surface of the second main body above the first main body.

2. The portable electronic device as claimed in claim 1, wherein the connection part comprises a pair of side hinge arms to provide the second hinge axis, and extending directions of the pair of the side hinge arms and the hinge part are perpendicular to each other.

3. The portable electronic device as claimed in claim 1, wherein the first main body comprises:
a plurality of first keys arranged in a QWERTY key array on an upper surface of the first main body;
a plurality of second keys positioned on a front surface of the first main body; and
a battery apparatus positioned on a bottom surface and adjacent to the hinge part, and
wherein the second main body comprises:
a plurality of third keys arranged in a number of keys array positioned on an inner surface of the second main body; and
a display unit positioned on the inner surface of the second main body and adjacent to the plurality of the third keys.

4. The portable electronic device as claimed in claim 3, wherein the connection part comprises a plurality of fourth keys arranged in a number of keys array and positioned on an outer surface of the connection part.

5. The portable electronic device as claimed in claim 1, wherein the connection part surrounds at least one half of a side surface of the second main body.

6. The portable electronic device as claimed in claim 3, wherein the plurality of the third keys and the fourth keys comprise a number of keys used in a DMB mode.

7. The portable electronic device as claimed in claim 1, wherein the second main body and the connection part have a shape corresponding to a shape of the first main body.

8. A portable electronic device comprising:
a QWERTY keypad extending in a longitudinal direction of the QWERTY keypad; and
a display unit connected to the keypad to be rotatable about a first hinge axis parallel to the longitudinal direction through use of a hinge part to be folded on or unfolded from the keypad, or be inclined with respect to the keypad, and rotatable about a second hinge axis parallel to the first hinge axis through use of a connection part formed on the hinge part to be turned over to switch an inner surface and an outer surface of the display unit above the keypad.

9. The portable electronic device as claimed in claim 8, wherein the connection part surrounds at least one half of a side surface of the display unit.

10. A portable electronic device comprising:
a data input unit; and
a data output unit connected to the data input unit to be rotatable about a first hinge axis parallel to a longitudinal direction of the data input unit through use of a hinge part to be folded on or unfolded from the data input unit, or be inclined with respect to the data input unit, and rotatable about a second hinge axis parallel to the first hinge axis through use of a connection part formed on the hinge part to be turned over to switch an inner surface and an outer surface of the data output unit above the data input unit.

11. The portable electronic device as claimed in claim 10, wherein the data output unit further comprises another data input unit, and the connection part further comprises still another data input unit.

12. The portable electronic device as claimed in claim 1, wherein the first main body comprises a plurality of first keys arranged in directional key and a 3×4 key array on an upper surface of the first main body.
